(19) United States
(12) Patent Application Publication
(10) Pub. No.: US 2010/0039129 A1
(43) Pub. Date: Feb. 18, 2010

(54) PROBE CARD

(75) Inventors: Ho Joon Park, Seoul (KR); Byeung Gyu Chang, Suwon (KR); Sang Jin Kim, Seoul (KR); Hee Ju Son, Suwon (KR)

Correspondence Address: MCDERMOTT WILL & EMERY LLP, 600 13TH STREET, N.W., WASHINGTON, DC, 20005-3096, US

(73) Assignee: SAMSUNG ELECTRO-MECHANICS CO., LTD.

(21) Appl. No.: 12/364,829

(22) Filed: Feb. 3, 2009

(30) Foreign Application Priority Data
Aug. 14, 2008 (KR) 10-2008-0080179

(51) Int. Cl. G01R 31/02; G01R 1/067

(52) U.S. Cl. 324/754

(57) ABSTRACT

Provided is a probe card. The probe card includes a ceramic substrate including a signal line, and a plurality of probe pins formed on the ceramic substrate, and including probe bodies having one end connected to the signal line and probe tips formed at other end of the probe body. The probe body is divided into a first section adjacent to the signal line and second section adjacent the probe tips. The first section is united by an insulating support, and the second sections are divergently arranged to position the probe tips at different measurement regions, respectively.

### CROSS-REFERENCE TO RELATED APPLICATIONS

This application claims the priority of Korean Patent Application No. 2008-0080179 filed on Aug. 14, 2008, in the Korean Intellectual Property Office, the disclosure of which is incorporated herein by reference.

### BACKGROUND OF THE INVENTION

1. Field of the Invention

The present invention relates to a probe card, and more particularly, to a probe card including a plurality of cantilever probe pins.

2. Description of the Related Art

Generally, a semiconductor test apparatus includes a tester, a performance board, a probe card, a chuck, and a prober to test electrical properties of chips on a wafer. The probe card of the semiconductor test apparatus receives a signal generated at the tester through the performance board, delivers the signal to pads of the chips in the wafer, and delivers a signal outputted from the pads of the chips to the tester through the performance board.

Generally, the probe card includes a probe pin to contact an electrode pad in a chip. As the sizes of the chips fabricated on a wafer are minimized in recent years, the size of the probe pin and an interval between the probe pins are progressively reduced. The probe pins are manufactured as much as the number of the electrode pads in the chip. If many probe pins are required, there is a limitation in manufacturing a plurality of probe pins in a given region.

### SUMMARY OF THE INVENTION

An aspect of the present invention provides a probe card capable of reducing an arrangement space of a probe pin, by unifying a first section of a probe body connected to a ceramic substrate and by mutually-separately arranging a second section of the probe body connected to a probe tip.

According to an aspect of the present invention, there is provided a probe card including: a ceramic substrate including a signal line; and a plurality of probe pins formed on the ceramic substrate, and including probe bodies having one end connected to the signal line and probe tips formed at other end of the probe body, the probe body being divided into a first section adjacent to the signal line and second sections adjacent the probe tips, the first section being united by an insulating support, the second section being divergently arranged to position the probe tips at different measurement regions, respectively.

The insulating support may be formed extending to the second section of the probe body.

The insulating support may include a parylene material.

The second sections of the probe bodes may be bent in different directions at a boundary between the first section and the second sections.

The second sections of the probe bodies may have different lengths.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a diagram illustrating a probe card according an embodiment of the present invention;

FIG. 2 is a diagram illustrating a probe pin according to an embodiment of the present invention;

FIGS. 3A to 3I are diagrams illustrating a method of manufacturing a probe card according to an embodiment of the present invention; and

FIG. 4 is a cross sectional view illustrating a probe card.

### DETAILED DESCRIPTION OF THE PREFERRED EMBODIMENT

Exemplary embodiments of the present invention will now be described in detail with reference to the accompanying drawings.

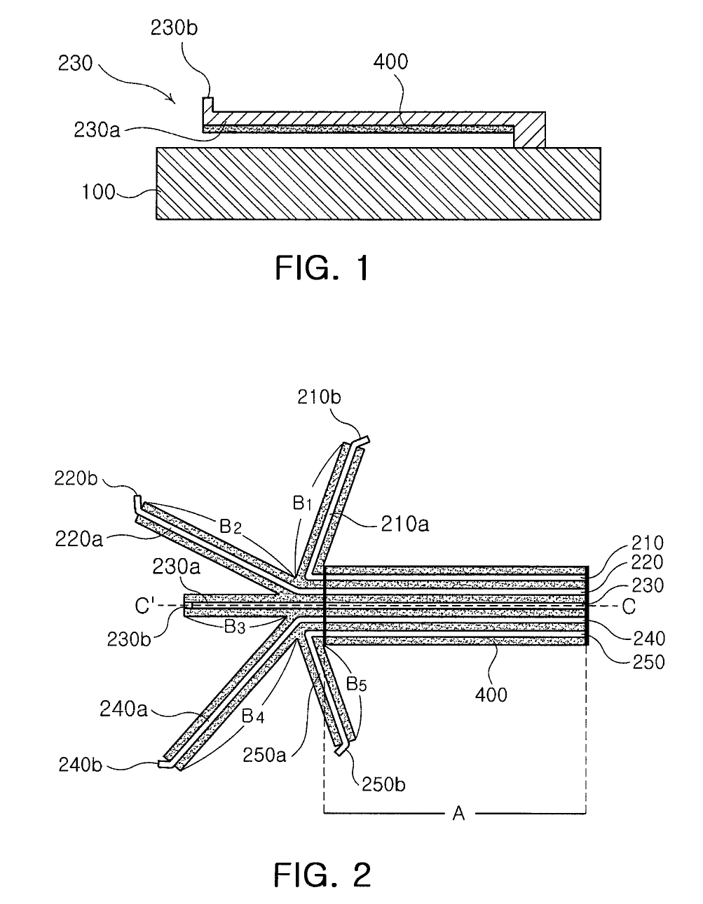

FIG. 1 is a diagram illustrating a probe card according an embodiment of the present invention. FIG. 2 is a diagram illustrating a probe pin applied to the probe card in FIG. 1.

The probe card as described in FIG. 1 includes a ceramic substrate 100 and a probe pin 230 bonded to the ceramic substrate 100. Although only one probe pin 230 is described in FIG. 1 due to a vertical cut along a line C-C′ in FIG. 2, a plurality of probe pins 210, 220, 230, 240 and 250 are formed on the ceramic substrate 100 as described in FIG. 2.

FIG. 2 is a plan view of the probe card as described in FIG. 1, which describes more clearly the plurality of probe pins 210, 220, 230, 240 and 250.

Referring to FIG. 2, the plurality of probe pins 210, 220, 230, 240 and 250 include probe bodies 210a, 220a, 230a, 240a and 250a having one end connected to a signal line (not shown) of the ceramic substrate 100, and probe tips 210b, 220b, 230b, 240b and 250b formed on the other end of the probe bodies 210a, 220a, 230a, 240a and 250a. In this case, the plurality of probe pins 210, 220, 230, 240, 250 is formed of at least one metal material of Nickel (Ni), Tungsten (W), Copper (Cu), and Silver(Ag). Also, each of the probe tips 210b, 220b, 230b, 240b and 250b may be exposed as a part delivering a measurement signal, and coated with a plating layer (not shown) of Gold (Au) or Nickel (Ni)

Each of probe bodies 210a, 220a, 230a, 240a and 250a is divided into a first section A adjacent to a signal line (not shown) of the ceramic substrate 100 and a second section B₁, B₂, B₃, B₄ and B₅ adjacent to each of probe tips 210b, 220b, 230b, 240b and 250b. In this case, each of probe bodies 210a, 220a, 230a, 240a and 250a in the first section A is united by an insulating support 400. That is, the insulating support 400 is formed between probe bodies 210a, 220a, 230a, 240a and 250a in the first section to electrically insulate the probe bodies 210a, 220a, 230a, 240a and 250a, and simultaneously fix the probe bodies 210a, 220a, 230a, 240a and 250a within the first section A. Accordingly, the first section A may have a plate shape. The insulating support 400 may include a parylene material. Also, the insulating support may be formed extending to the second section B₁, B₂, B₃, B₄ and B₅ of each of the probe bodies 210a, 220a, 230a, 240a and 250a.

The second section B₁, B₂, B₃, B₄ and B₅ of each of the probe bodies 210a, 220a, 230a, 240a and 250a are divergently arranged so that each of the probe tips 210b, 220b, 230b, 240b and 250b is located at a different measurement region. More concretely, the second section B₁, B₂, B₃, B₄ and B₅ of each of the probe bodies 210a, 220a, 230a, 240a and 250a have a different length from each other, and are bent in a different direction on the basis of a boundary between the first section A and the second section B₁, B₂, B₃, B₄ and B₅. Accordingly, the second section B₁, B₂, B₃, B₄ and B₅ of each of the probe bodies 210a, 220a, 230a, 240a and 250a may be extended to circumferential region except the first section A of the probe bodies 210a, 220a, 230a, 240a and 250a. By using this feature, the second section B₁, B₂, B₃, B₄ and B₅ of each of the probe bodies 210a, 220a, 230a, 240a and 250a may cover distant measurement regions as well as close measurement regions. Accordingly, the measurable region by the plurality of probe pins 210, 220, 230, 240, 250 may be magnified.

In the plurality of probe pins 210, 220, 230, 240, 250 as described in FIG. 2, the first section A of the probe bodies 210a, 220a, 230a, 240a and 250a is unified in a plate shape by the insulating support 400 to be formed in a plate shape. Meanwhile, more number of probe pins than the plurality of probe pins 210, 220, 230, 240, 250 as described in FIG. 2 may be formed in a bunch or multi-layer of probe pins. When the plurality of probe pins 210, 220, 230, 240, 250 are formed in a bunch or multi-layer of probe pins, the probe tips connected to the second section B₁, B₂, B₃, B₄ and B₅ of each of the probe bodies 210a, 220a, 230a, 240a and 250a may have a different length from each other.

As described above, the first section A of the probe bodies 210a, 220a, 230a, 240a and 250a is unified, and the second section B₁, B₂, B₃, B₄ and B₅ of each of the probe bodies 210a, 220a, 230a, 240a and 250a are divergently arranged. As a result, the measurable regions by the plurality of probe pins 210, 220, 230, 240, 250 can be magnified. Also, the arrangement space by the plurality of probe pins 210, 220, 230, 240, 250 can be reduced.

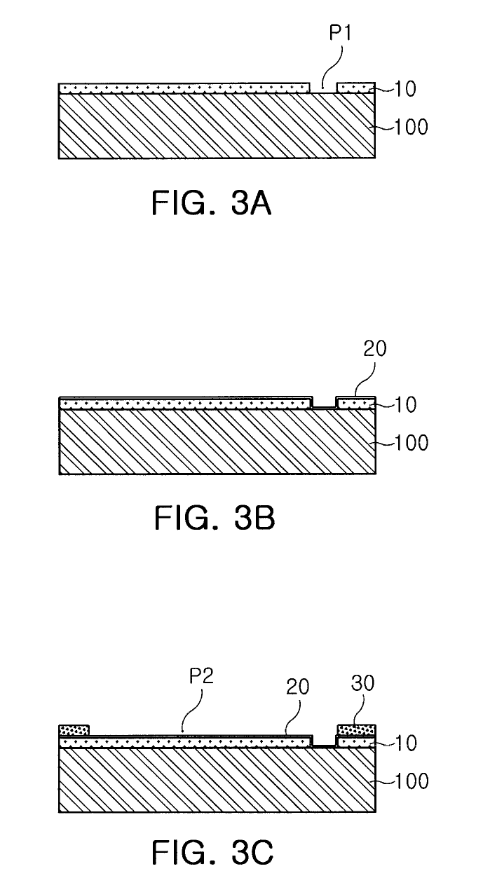

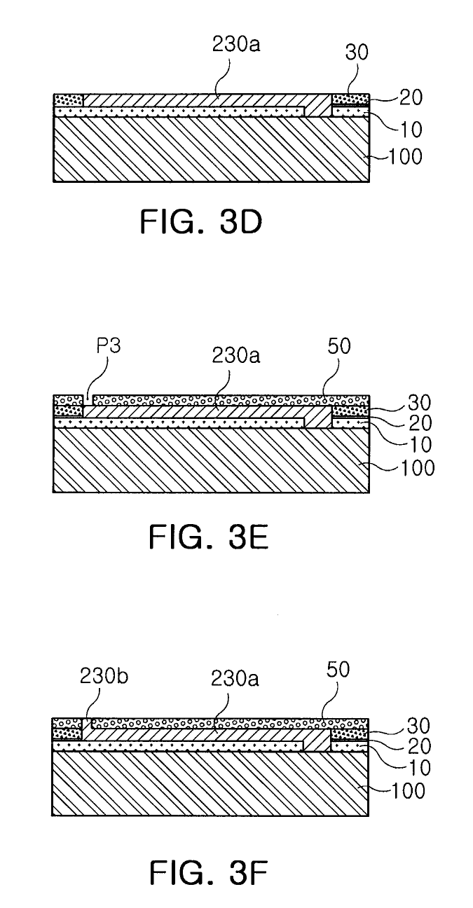

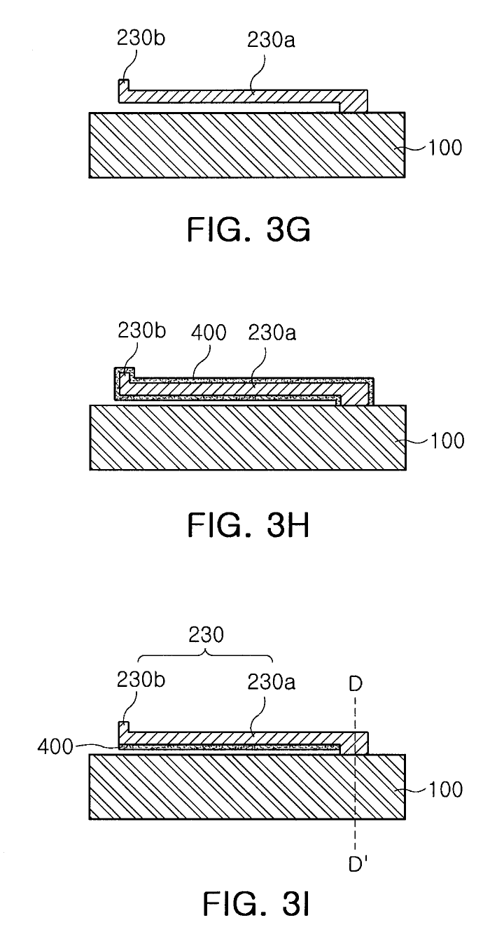

FIGS. 3A to 3I are diagrams illustrating a method of manufacturing a probe card according to an embodiment of the present invention. FIGS. 3A to 3D are diagrams illustrating a method of forming a probe bodies on a ceramic substrate. More concretely, as described FIG. 3A, a first pattern P1 is formed by exposing a ceramic substrate 100 coated with a photoresist 10. In this case, the ceramic substrate 100 may be exposed through the first pattern P1. That is, a part of the ceramic substrate 100 at which a signal line is located may be exposed.

As described in FIG. 3B, a plating seed layer 20 is formed on the photoresist 10 and the ceramic substrate 100 exposed through the first pattern P1. Then, as described in FIG. 3C, a second pattern P2 may be formed by exposing a photoresist 30 coated on the plating seed layer 20. In this case, a sacrificial layer (not shown) may be formed of a material such as SiO₂ on the plating seed layer 20 formed on the first pattern P1 before the photoresist 30 is coated. Then, if the second pattern P2 is formed, the sacrificial layer is removed.

The first and second patterns P1 and P2 as described in FIGS. 3A and 3B may be a region for forming a probe body. For a convenient explanation, only one pattern for forming the probe body is described in FIGS. 3A and 3B, but substantially, a plurality of patterns are formed in order to form the probe bodies around the first and second patterns P1 and P2.

The plurality of patterns may have a different length from the first and second patterns P1 and P2. Also, the plurality of patterns may have a bent pattern of a different angle from each other.

As described in FIG. 3D, a probe body 230a is formed by filling at. least one of Ni, W, Cu, and Ag in the first and second patterns P1 and P2. In this case, although not shown in FIGS. 3A to 3D, a plurality of probe bodies are formed besides the probe body 230a.

On the other hand, as described in FIG. 3E, a photoresist 50 is subsequently coated on the probe body 230a and the photoresist 30. Then, the photoresist 50 is exposed to form a third pattern P₃ for a probe tip. And then, a metal material is filled in the third pattern P₃ to form a probe tip 230b. Accordingly, a structure having the probe pin 230 therein is formed as described in FIG. 3F.

As described in FIG. 3G, the photoresists 10, 30 and 50 are removed to form a complete probe pin 230 on the ceramic substrate 100. In this case, although not shown in the drawings, a plurality of probe pins are formed at either side of the probe pin 230.

As described in FIG. 3H, an insulating support 400 is formed over a probe pin formed on the ceramic substrate 100. In this case, the insulating support 400 may be formed of parylene. More concretely, a method of depositing a powder-type parylene dimer on the probe pin 230 using a deposition chamber may be used to form the insulating support 400. In this case, the insulating support 400 may be deposited in a thin layer of several micrometers, and have elastic and insulating properties. Thus, the insulating support 400 is located between the plurality of probe pins 210, 220, 230, 240 and 250 to electrically insulate the plurality of probe pins 210, 220, 230, 240, 250 therebetween.

As described in FIG. 3I, the insulating support 400 is etched using a reactive ion etching process (RIE). In this case, the parylene material has a different etching rate according to an etching direction. Generally, an etching rate of a vertical direction is greater than an etching rate of a lateral direction. Accordingly, although the parylene material on the upper surface of the probe pin 230 is etched to expose the upper surface of the probe pin 230, the parylene material on the side and lower surface of the probe pin 230 still remains. In this case, the plurality of probe pins 210, 220, 230, 240, 250 may be electrically insulated by the insulating support 400 located therebetween.

By the etching process, the probe tip 230b may be exposed to the outside to electrically contact the measurement regions.

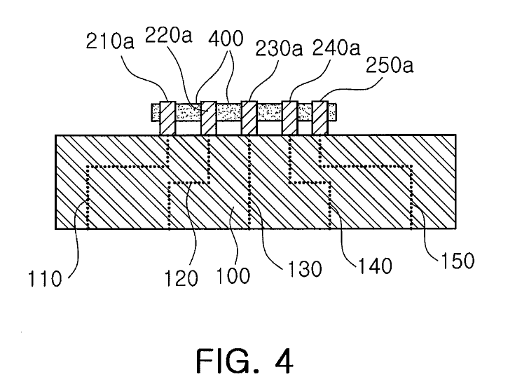

FIG. 4 is a cross sectional view illustrating a probe card. More concretely, FIG. 4 is a cross sectional view taken along a line D-D′ in FIG. 3I. The part corresponding to the line D-D′ is a part at which first to fifth signal lines 110, 120, 130, 140 and 150 are located in the ceramic substrate 100.

Referring to FIG. 4, the plurality of probe bodies 210a, 220a, 230a, 240a and 250a are connected to the first to fifth signal lines 110, 120, 130, 140 and 150, respectively. Accordingly, the plurality of probe bodies 210a, 220a, 230a, 240a and 250a may receive measurement signals from the first to fifth signal lines 110, 120, 130, 140 and 150. In this case, the plurality of probe bodies 210a, 220a, 230a, 240a and 250a are electrically insulated by the insulating support 400 formed therebetween, and united by the insulating support 400 to have a plate-like structure. Also, the insulating support 400 is elastic enough to protect the plurality of probe pins from an external shock.

According to the embodiment of the present invention, the first section of the probe body connected to the ceramic substrate is unified. Also, the second section of the probe body connected to the probe tip is mutually-separately arranged. According, more probe pins can be formed in a given region because the arrangement space for the plurality of probe pins is reduced.

Also, the measurement region by the plurality of probe pins can be expanded by forming parts of the probe body connected to the probe tip with a different length and bending the parts into a different direction.

While the present invention has been shown and described in connection with the exemplary embodiments, it will be apparent to those skilled in the art that modifications and variations can be made without departing from the spirit and scope of the invention as defined by the appended claims.

What is claimed is:

1. A probe card comprising:
a ceramic substrate comprising a signal line; and
a plurality of probe pins formed on the ceramic substrate, and comprising probe bodies having one end connected to the signal line and probe tips formed at other end of the probe body,
the probe body being divided into a first section adjacent to the signal line and second sections adjacent the probe tips, the first section being united by an insulating support, the second section being divergently arranged to position the probe tips at different measurement regions, respectively.

2. The probe card of claim 1, wherein the insulating support is formed extending to the second section of the probe body.

3. The probe card of claim 2, wherein the insulating support comprises a parylene material.

4. The probe card of claim 1, wherein the second sections of the probe bodes are bent in different directions at a boundary between the first section and the second sections.

5. The probe card of claim 1, wherein the second sections of the probe bodies have different lengths.
